(19) United States
(12) Patent Application Publication
(10) Pub. No.: US 2025/0233604 A1
(43) Pub. Date: Jul. 17, 2025

(54) SIGNAL PROCESSING CIRCUIT AND SENSOR UNIT

(71) Applicant: TDK Corporation, Tokyo (JP)

(72) Inventor: Keita MIYACHI, Tokyo (JP)

(73) Assignee: TDK Corporation, Tokyo (JP)

(21) Appl. No.: 18/915,382

(22) Filed: Oct. 15, 2024

(30) Foreign Application Priority Data
Jan. 11, 2024 (JP) 2024-002335

(51) Int. Cl. H04B 1/04

(52) U.S. Cl. CPC H04B 1/04

(57) ABSTRACT

A signal processing circuit includes: a first element and a second element connected in series to each other between a first DC power supply and ground, with respective resistance values thereof varying in response to a change in a physical amount of an observation target; an operational amplifier having an inverting input terminal connected to a midpoint between the first element and the second element, a non-inverting input terminal connected to a second DC power supply, and an output terminal; and a feedback resistance connected between the output terminal and the inverting input terminal.

### CROSS-REFERENCE TO RELATED APPLICATION

The present application is based upon and claims the benefit of priority from Japanese Patent Application No. 2024-002335, filed on Jan. 11, 2024, the entire contents of which are hereby incorporated by reference.

### BACKGROUND

The present disclosure relates to a signal processing circuit and a sensor unit.

For example, bridge resistance sensors have been known where a plurality of resistive elements such as magneto resistive (MR) elements that detect the magnitude of a magnetic field are arranged and bridge-connected. There have been typically known signal processing circuits for bridge resistance sensors that connect their output signal to a non-inverting input terminal having higher input resistance among the input terminals of an operational amplifier to obtain an amplified voltage signal (see, for example, Patent Publication JP-A-2014-89087).

### SUMMARY

A signal processing circuit according to a first aspect of the present disclosure includes: a first element and a second element connected in series to each other between a first DC power supply and ground, with respective resistance values thereof varying in response to a change in a physical amount of an observation target; an operational amplifier having an inverting input terminal connected to a midpoint between the first element and the second element, a non-inverting input terminal connected to a second DC power supply, and an output terminal; and a feedback resistance connected between the output terminal and the inverting input terminal.

Further, a signal processing circuit according to a second aspect of the present disclosure includes: a full-bridge circuit formed collectively by a combination of a first element and a second element connected in series to each other between a first DC power supply and ground, with respective resistance values thereof varying in response to a change in a physical amount of an observation target, and by a combination of a third element and a fourth element connected in series to each other between the first DC power supply and the ground, with respective resistance values thereof varying in response to the change in the physical amount; a differential operational amplifier having an inverting input terminal connected to a midpoint between the first element and the second element, a non-inverting input terminal connected to a midpoint between the third element and the fourth element, a first output terminal, and a second output terminal; a first feedback resistance connected between the first output terminal and the inverting input terminal; and a second feedback resistance connected between the second output terminal and the non-inverting input terminal.

Further, a sensor unit according to a third aspect of the present disclosure includes the above signal processing circuit.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a diagram illustrating an example of the usage aspect of a magnetic sensor unit according to this example embodiment;

FIG. 2 is a circuit diagram of a signal processing circuit according to a first example of this example embodiment;

FIG. 3 is a diagram illustrating the circuit configuration of a telescopic operational amplifier;

FIG. 4 is a circuit diagram of a signal processing circuit according to a second example of this example embodiment; and

FIG. 5 is a circuit diagram of a signal processing circuit according to a third example of this example embodiment.

### DETAILED DESCRIPTION

In the case of a signal processing circuit that connects an output signal from a bridge resistance sensor to the non-inverting input terminal of an operational amplifier, there is a problem where power used to maintain a noise level within a constant range increases if an amplitude range (an AC voltage component+a DC voltage component) that may be taken by the output signal increases.

The present disclosure has been made to solve such a problem and provides a signal processing circuit that may suppress power consumption even when the amplitude range of an output signal from a bridge resistance sensor increases.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

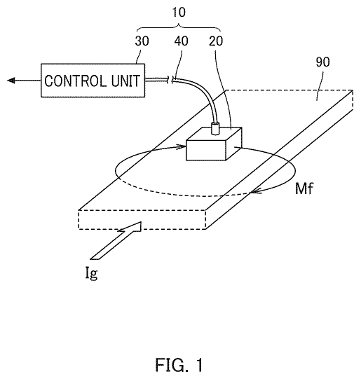

FIG. 1 is a diagram illustrating an example of the usage aspect of a magnetic sensor unit 10 according to this example embodiment. The magnetic sensor unit 10 may be composed of a sensor head 20 including a signal processing circuit that will be described later, a control unit 30 that controls the sensor head 20 and processes a detection signal output from the sensor head 20, and a cable 40 that connects the sensor head 20 and the control unit 30.

The sensor head 20 is installed, for example, within the range of a magnetic field Mf generated by a current Ig flowing through a bus bar 90, and outputs a detection signal corresponding to the intensity of the magnetic field Mf. The control unit 30 receives the detection signal from the sensor head 20 via the cable 40, and transmits the detection signal to an external device such as a current analysis device after subjecting the same, for example, to AD conversion. The intensity of the magnetic field Mf varies according to the current Ig. Therefore, the magnetic sensor unit 10 may be used as a current sensor that detects the current Ig flowing through the bus bar 90. Note that the sensor head 20 and the control unit 30 of the magnetic sensor unit 10 are configured separately in this example embodiment, but they may also be integrated.

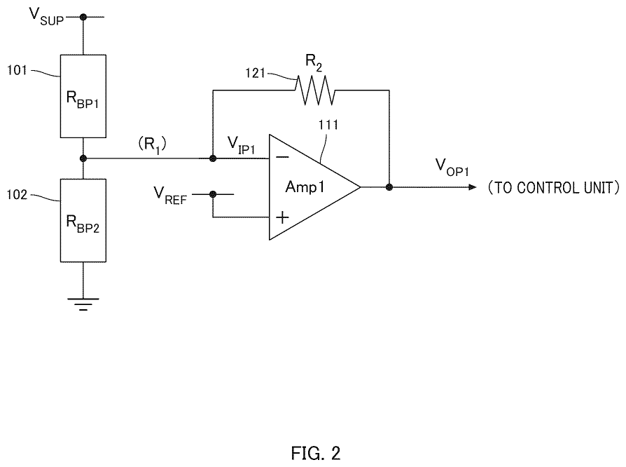

FIG. 2 is a circuit diagram of the signal processing circuit according to a first example of this example embodiment. The signal processing circuit constitutes the sensor head 20 and may include a first element 101, a second element 102, a first operational amplifier 111, and a first feedback resistance 121.

Each of the first element 101 and the second element 102 is, for example, a spin valve magneto resistive effect element (MR element) whose resistance value varies according to changes in a magnetic field, which represents a physical amount as an observation target. The first element 101 and the second element 102 are connected in series to each other between a first DC power supply and ground to constitute a half-bridge circuit. The first DC power supply supplies a constant supply voltage V_{SUP} to the half-bridge circuit. The first element 101 and the second element 102 are arranged so that their magnetic detection axes oppose each other, and a resistance value R_{BP1} of the first element 101 and a resistance value R_{BP2} of the second element 102 vary complementarily in response to an applied magnetic field. Accordingly, a voltage at the midpoint between the first element 101 and the second element 102 varies in response to the intensity of an applied magnetic field. That is, the first element 101 and the second element 102 constituted as a half-bridge circuit functions as a magnetic sensor that outputs a voltage signal corresponding to the intensity of an applied magnetic field from the midpoint. Note that the “midpoint” refers to a point on a connection line connecting the first element 101 and the second element 102.

The first operational amplifier 111 has an inverting input terminal, a non-inverting input terminal, and an output terminal. The inverting input terminal is connected to the midpoint between the first element 101 and the second element 102. The non-inverting input terminal is connected to a second DC power supply. The second DC power supply supplies a constant supply voltage V_{REF} to the non-inverting input terminal. The first feedback resistance 121 is a fixed resistance that is connected between the output terminal and the non-inverting input terminal of the first operational amplifier 111 and has a constant resistance value R₂.

When a resistance value at the midpoint between the first element 101 and the second element 102, that is, a bridge output resistance value serving as an input resistance value to the inverting input terminal is represented as R₁, closed-loop gain at the inverting input terminal becomes −R₂/R₁. At this time, negative feedback control is applied as a characteristic of the first operational amplifier 111 serving as an operational amplifier so that a first signal voltage V_{IP1} input to the inverting input terminal becomes equal to a supply voltage V_{REF} supplied from the second DC power supply to the non-inverting input terminal. As a result, a first output voltage V_{OP1} output from the output terminal of the first operational amplifier 111 becomes a voltage signal that varies in response to the intensity of a magnetic field applied to the first element 101 and the second element 102.

Note that a minimum value R_{1MIN} of the bridge output resistance value R₁ that varies may be greater than a resistance value R₂ of the first feedback resistance 121. When such a relationship is established, the followability of the first output voltage V_{OP1} output from the output terminal of the first operational amplifier 111 with respect to changes in an output voltage output from the midpoint between the first element 101 and the second element 102 is excellent.

Further, as a result of the feedback control applied so that the first signal voltage V_{IP1} input to the inverting input terminal becomes equal to the supply voltage V_{REF} that is a constant voltage, the amplitude range of the voltage input to both the input terminals of the operational amplifier is suppressed to a very small range. The signal processing circuit having such characteristics may employ a telescopic operational amplifier as the first operational amplifier 111.

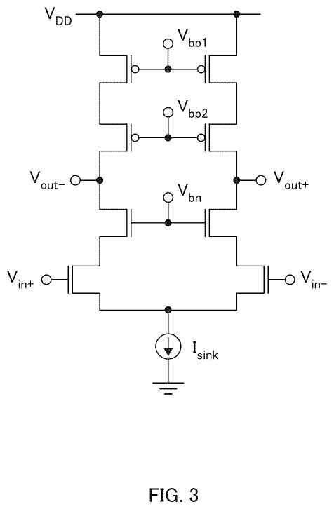

FIG. 3 is a diagram illustrating the circuit configuration of a telescopic operational amplifier. In the telescopic operational amplifier, the difference between V_{DD} and Vᵢₙ is small. Therefore, the allowable amplitude range of Vᵢₙ is limited and smaller compared to other types of operational amplifiers. On the other hand, the current path between V_{DD} and ground is smaller compared to other types of operational amplifiers. Therefore, power consumption used to operate the operational amplifier may be suppressed.

As described above, in the signal processing circuit according to the first example, the amplitude range of the voltage input to both the input terminals is suppressed to a very small range. Therefore, the disadvantage concerning the amplitude range of the telescopic operational amplifier may be ignored. Accordingly, if the telescopic operational amplifier is employed as the first operational amplifier 111, the benefit of low power consumption may be realized without causing any particular inconvenience.

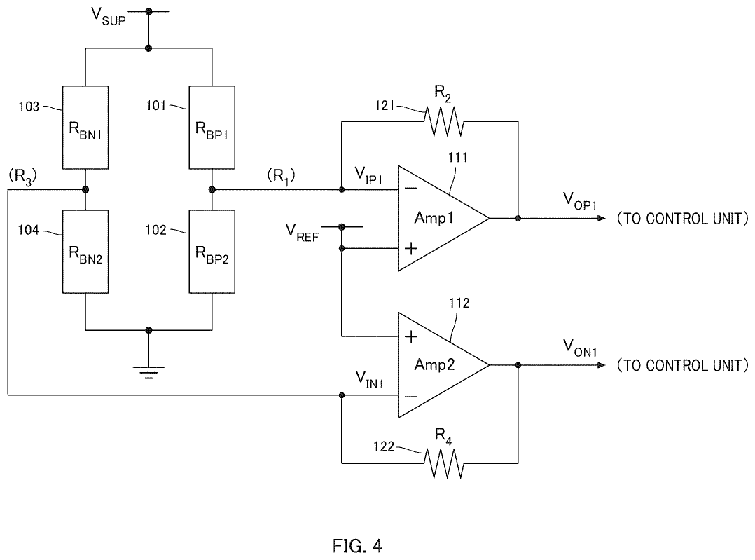

Next, a signal processing circuit according to a second example of this example embodiment will be described. The signal processing circuit according to the first example employs a configuration where a magnetic sensor constituted as a half-bridge circuit is combined with an inverting single-ended amplifier. On the other hand, the signal processing circuit according to the second example employs a configuration where a magnetic sensor constituted as a full-bridge circuit is combined with inverting differential amplifiers. FIG. 4 is a circuit diagram of the signal processing circuit according to the second example of this example embodiment. The signal processing circuit according to the second example includes the signal processing circuit according to the first example. Therefore, common elements will be denoted by the same symbols, and their descriptions will be omitted unless otherwise specifically mentioned.

The signal processing circuit constitutes the sensor head 20 like the signal processing circuit according to the first example, and may include a first element 101, a second element 102, a third element 103, a fourth element 104, a first operational amplifier 111, a second operational amplifier 112, a first feedback resistance 121, and a second feedback resistance 122.

The third element 103 and the fourth element 104 are also, for example, spin valve magneto resistive effect element (MR elements) whose resistance values vary according to changes in a magnetic field like the first element 101 and the second element 102. The first element 101 and the second element 102 are connected in series to each other between a first DC power supply and ground, and the third element 103 and the fourth element 104 are also connected in series to each other between the first DC power supply and the ground, thus collectively constituting a full-bridge circuit. The first DC power supply supplies a constant supply voltage V_{SUP} to the full-bridge circuit.

The third element 103 and the fourth element 104 are arranged so that their magnetic detection axes oppose each other. In addition, the third element 103 and the second element 102 are arranged so that their magnetic detection axes are oriented in the same direction, and the fourth element 104 and the first element 101 are arranged so that their magnetic detection axes are oriented in the same direction. Just as a resistance value R_{BP1} of the first element 101 and a resistance value R_{BP2} of the second element 102 vary complementarily in response to an applied magnetic field, a resistance value R_{BN1} of the third element 103 and a resistance value R_{BN2} of the fourth element 104 also vary complementarily in response to the applied magnetic field. Accordingly, just as a voltage at the midpoint between the first element 101 and the second element 102 varies in response to the intensity of an applied magnetic field, a voltage at the midpoint between the third element 103 and the fourth element 104 also varies in response to the intensity of the applied magnetic field. Further, each of the elements is arranged with the direction of its magnetic detection axis adjusted as described above. Therefore, the voltages at the respective midpoints vary in such a manner that when one voltage increases, the other voltage decreases. That is, the first element 101 to the fourth element 104 constituted as a full-bridge circuit function as a magnetic sensor that outputs a voltage signal inversely correlated to the intensity of an applied magnetic field from each of the two midpoints.

The second operational amplifier 112 has the same configuration as that of the first operational amplifier 111, and also has the same connection relationships with other elements as those of the first operational amplifier 111. Specifically, the second operational amplifier 112 has an inverting input terminal, a non-inverting input terminal, and an output terminal. The inverting input terminal is connected to the midpoint between the third element 103 and the fourth element 104. The non-inverting input terminal is connected to a second DC power supply. That is, both the non-inverting input terminals of the two operational amplifiers are connected to the second DC power supply common to the non-inverting input terminals. The second feedback resistance 122 is a fixed resistance that is connected between the output terminal and the inverting input terminal of the second operational amplifier 112 and has a constant resistance value R₄.

When a resistance value at the midpoint between the third element 103 and the fourth element 104, that is, a bridge output resistance value serving as an input resistance value to the inverting input terminal is represented as R₃, closed-loop gain at the inverting input terminal becomes −R₃/R₄. At this time, negative feedback control is applied as a characteristic of the second operational amplifier 112 serving as an operational amplifier so that a second signal voltage V_{IN1} input to the inverting input terminal becomes equal to a supply voltage V_{REF} supplied from the second DC power supply to the non-inverting input terminal. As a result, a second output voltage V_{ON1} output from the output terminal of the second operational amplifier 112 becomes a voltage signal that varies in response to the intensity of a magnetic field applied to the third element 103 and the fourth element 104. Note that a minimum value R_{3MIN} of the bridge output resistance value R₃ that varies may be greater than a resistance value R₄ of the second feedback resistance 122. Further, the resistance value R₂ of the first feedback resistance 121 may be equal to the resistance value R₄ of the second feedback resistance 122. Further, telescopic operational amplifiers may be employed as the first operational amplifier 111 and the second operational amplifier 112.

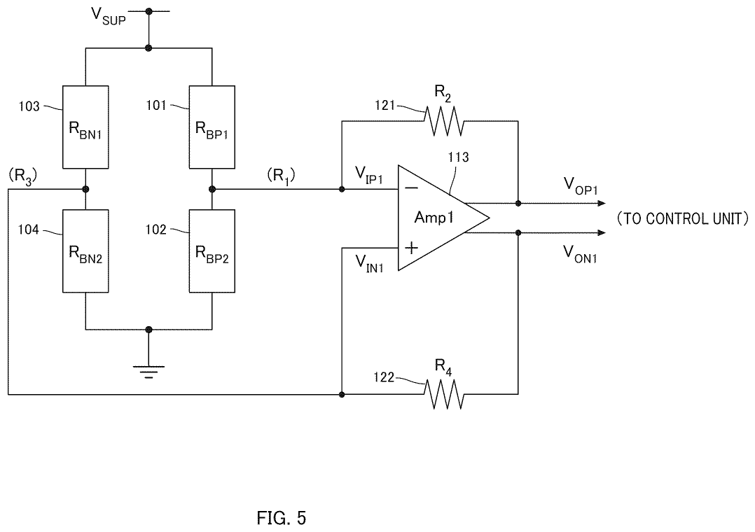

Moreover, a signal processing circuit according to a third example of this example embodiment will be described. The signal processing circuit according to the second example employs a configuration where the output of a full-bridge circuit is received by two operational amplifiers. On the other hand, the signal processing circuit according to the third example employs a configuration where the output of a magnetic sensor constituted as a full-bridge circuit is received by one differential operational amplifier and differentially output from the two output terminals of the differential operational amplifier. FIG. 5 is a circuit diagram of the signal processing circuit according to the third example of this example embodiment. The signal processing circuit according to the third example partially includes the signal processing circuit according to the first example. Therefore, the same elements will be denoted by the same symbols, and their descriptions will be omitted unless otherwise specifically mentioned.

The signal processing circuit according to the third example constitutes the sensor head 20 like the signal processing circuit according to the first example, and may include a first element 101, a second element 102, a third element 103, a fourth element 104, a differential operational amplifier 113, a first feedback resistance 121, and a second feedback resistance 122.

The third element 103 and the fourth element 104 are also, for example, spin valve magneto resistive effect elements (MR elements) whose resistance values vary according to changes in a magnetic field like the first element 101 and the second element 102. The first element 101 and the second element 102 are connected in series to each other between a first DC power supply and ground, and the third element 103 and the fourth element 104 are also connected in series to each other between the first DC power supply and the ground, thus collectively constituting a full-bridge circuit. The first DC power supply supplies a constant supply voltage V_{SUP} to the full-bridge circuit.

The third element 103 and the fourth element 104 are arranged so that their magnetic detection axes oppose each other. In addition, the third element 103 and the second element 102 are arranged so that their magnetic detection axes are oriented in the same direction, and the fourth element 104 and the first element 101 are arranged so that their magnetic detection axes are oriented in the same direction. Just as a resistance value R_{BP1} of the first element 101 and a resistance value R_{BP2} of the second element 102 vary complementarily in response to an applied magnetic field, a resistance value R_{BN1} of the third element 103 and a resistance value R_{BN2} of the fourth element 104 also vary complementarily in response to the applied magnetic field. Accordingly, just as a voltage at the midpoint between the first element 101 and the second element 102 varies in response to the intensity of an applied magnetic field, a voltage at the midpoint between the third element 103 and the fourth element 104 also varies in response to the intensity of the applied magnetic field. Further, each of the elements is arranged with the direction of its magnetic detection axis adjusted as described above. Therefore, the voltages at the respective midpoints vary in such a manner that when one voltage increases, the other voltage decreases. That is, the first element 101 to the fourth element 104 constituted as a full-bridge circuit function as a magnetic sensor that outputs a voltage signal inversely correlated to the intensity of an applied magnetic field from each of the two midpoints.

The differential operational amplifier 113 includes a first output terminal and a second output terminal that provide differential output for an input signal. The midpoint between the first element 101 and the second element 102 is connected to an inverting input terminal, and a first feedback resistance 121 is connected between the first output terminal and the inverting input terminal. The first feedback resistance 121 is a fixed resistance having a constant resistance value R₂. Further, the midpoint between the third element 103 and the fourth element 104 is connected to a non-inverting input terminal, and a second feedback resistance 122 is connected between the second output terminal and the non-inverting input terminal. The second feedback resistance 122 is a fixed resistance having a constant resistance value R₄.

When a resistance value at the midpoint between the first element 101 and the second element 102, that is, a bridge output resistance value serving as an input resistance value to the inverting input terminal is represented as R₁, closed-loop gain at the inverting input terminal becomes-R₂/R₁. Further, when a resistance value at the midpoint between the third element 103 and the fourth element 104, that is, a bridge output resistance value serving as an input resistance value to the non-inverting input terminal is represented as R₃, closed-loop gain at the non-inverting input terminal becomes R₃/R₄. At this time, negative feedback control is applied as a characteristic of the differential operational amplifier 113 serving as an operational amplifier so that a first signal voltage V_{IP1} input to the inverting input terminal becomes equal to a second signal voltage V_{IN1} supplied to the non-inverting input terminal. As a result, each of a first output voltage V_{OP1} output from the first output terminal of the differential operational amplifier 113 and a second output voltage V_{ON1} output from the second output terminal of the operational amplifier 113 becomes a voltage signal corresponding to the difference between the first signal voltage V_{IP1} and the second signal voltage V_{IN1}.

Note that a minimum value R_{1MIN} of the bridge output resistance value R₁ that varies may be greater than the resistance value R₂ of the first feedback resistance 121. Similarly, a minimum value R_{3MIN} of the bridge output resistance value R₃ that varies may be greater than the resistance value R₄ of the second feedback resistance 122. Further, the resistance value R₂ of the first feedback resistance 121 may be equal to the resistance value R₄ of the second feedback resistance 122. Further, a telescopic operational amplifier may be employed as the differential operational amplifier 113.

In this example embodiment described above, a case where the magnetic sensor unit 10 is used as a current sensor to detect the current Ig flowing through the bus bar 90 is assumed. However, the magnetic sensors employing the signal processing circuits according to the first to third examples may not be used only as current sensors. The magnetic sensors may be employed not only as current sensors but also as angular sensors, direction sensors (compasses), position sensors, or the like. Particularly, the magnetic sensors are useful as sensors that demand low power consumption.

Further, in this example embodiment described above, the magnetic sensors are described as applied examples. Therefore, the magneto resistive effect elements are employed as resistive elements. However, the resistive elements incorporated into the signal processing circuits may only be elements whose resistance values vary in response to changes in the physical amount of an observation target. In this case, the signal processing circuits function as sensors that detect the physical amount of the observation target.

Hereinafter, the specific aspects and effects of the present disclosure will be briefly summarized. A signal processing circuit according to a first aspect of the present disclosure includes: a first element and a second element connected in series to each other between a first DC power supply and ground, with respective resistance values thereof varying in response to a change in a physical amount of an observation target; an operational amplifier having an inverting input terminal connected to a midpoint between the first element and the second element, a non-inverting input terminal connected to a second DC power supply, and an output terminal; and a feedback resistance connected between the output terminal and the inverting input terminal.

In the operational amplifier of the signal processing circuit connected as described above, negative feedback control is applied so that an input voltage input to the inverting input terminal becomes equal to the voltage of the second DC power supply input to the non-inverting input terminal even if an output voltage output from the midpoint between the first element and the second element varies. As a result, the amplitude range of the voltage input to both the input terminals is suppressed to a very small range. Therefore, power consumed in the signal processing circuit may be significantly suppressed.

In the above signal processing circuit, a minimum value of an input resistance value to the inverting input terminal determined by the respective resistance values of the first element and the second element may be greater than a resistance value of the feedback resistance. When such a relationship is established, the followability of an output voltage output from the output terminal of the operational amplifier with respect to changes in the output voltage output from the midpoint between the first element and the second element is excellent.

Further, the above signal processing circuit may be composed of two sets of the first elements and the second elements, which collectively form a full-bridge circuit, two sets of the operational amplifiers, and two sets of the feedback resistances, and the respective non-inverting input terminals of the two operational amplifiers may be connected to the second DC power supply common to the non-inverting input terminals. In the signal processing circuit where the four resistive elements are connected as a so-called full bridge as described above, power consumed in the signal processing circuit may be significantly suppressed like a signal processing circuit where two resistive elements are connected as a half bridge. Both the signal processing circuit with the two resistive elements connected as a half bridge and the signal processing circuit with the four resistive elements connected as a full bridge are more practical when used with magnetic sensors, particularly those where resistive elements are represented by MR elements.

Further, the operational amplifier employed in the above signal processing circuit may be a telescopic operational amplifier. In the telescopic operational amplifier, the amplitude range of an allowable input voltage is inherently small. Therefore, the telescopic operational amplifier is rarely employed for the amplitude range of an output voltage assumed in the present disclosure. However, in the present disclosure, the amplitude range of a voltage input to input terminals is suppressed to a very small range, thus making it possible to employ the telescopic operational amplifier. As a result, the benefit of the characteristics of low power consumption may be realized.

Further, a signal processing circuit according to a second aspect of the present disclosure includes: a full-bridge circuit formed collectively by a combination of a first element and a second element connected in series to each other between a first DC power supply and ground, with respective resistance values thereof varying in response to a change in a physical amount of an observation target, and by a combination of a third element and a fourth element connected in series to each other between the first DC power supply and the ground, with respective resistance values thereof varying in response to the change in the physical amount; a differential operational amplifier having an inverting input terminal connected to a midpoint between the first element and the second element, a non-inverting input terminal connected to a midpoint between the third element and the fourth element, a first output terminal, and a second output terminal; a first feedback resistance connected between the first output terminal and the inverting input terminal; and a second feedback resistance connected between the second output terminal and the non-inverting input terminal.

Even in the signal processing circuit where the output terminals of the full-bridge circuit are connected to the inverting input terminal and the non-inverting input terminal of the differential operational amplifiers, respectively, power consumed in the signal processing circuit may be significantly suppressed.

Further, a sensor unit according to a third aspect of the present disclosure includes the above signal processing circuit. When unitized as a sensor unit, the above signal processing circuit is incorporated into various devices and easily used.

By the example embodiments described above, the signal processing circuits that suppress power consumption even when the amplitude range of an output signal from a bridge resistance sensor increases may be provided.

1. A signal processing circuit comprising:
a first element and a second element connected in series to each other between a first DC power supply and ground, with respective resistance values thereof varying in response to a change in a physical amount of an observation target;
an operational amplifier having an inverting input terminal connected to a midpoint between the first element and the second element, a non-inverting input terminal connected to a second DC power supply, and an output terminal; and
a feedback resistance connected between the output terminal and the inverting input terminal.

2. The signal processing circuit according to claim 1, wherein
a minimum value of an input resistance value to the inverting input terminal determined by the respective resistance values of the first element and the second element is greater than a resistance value of the feedback resistance.

3. The signal processing circuit according to claim 1, wherein
the signal processing circuit is composed of
two sets of the first elements and the second elements, which collectively form a full-bridge circuit,
two sets of the operational amplifiers, and
two sets of the feedback resistances, and
the respective non-inverting input terminals of the two operational amplifiers are connected to the second DC power supply common to the non-inverting input terminals.

4. The signal processing circuit according to claim 1, wherein
each of the first element and the second element is a magnetic sensor.

5. The signal processing circuit according to claim 1, wherein
the operational amplifier is a telescopic operational amplifier.

6. A signal processing circuit comprising:
a full-bridge circuit formed collectively by a combination of a first element and a second element connected in series to each other between a first DC power supply and ground, with respective resistance values thereof varying in response to a change in a physical amount of an observation target, and by a combination of a third element and a fourth element connected in series to each other between the first DC power supply and the ground, with respective resistance values thereof varying in response to the change in the physical amount;
a differential operational amplifier having an inverting input terminal connected to a midpoint between the first element and the second element, a non-inverting input terminal connected to a midpoint between the third element and the fourth element, a first output terminal, and a second output terminal;
a first feedback resistance connected between the first output terminal and the inverting input terminal; and
a second feedback resistance connected between the second output terminal and the non-inverting input terminal.

7. The signal processing circuit according to claim 6, wherein
each of the first element to the fourth element is a magnetic sensor.

8. The signal processing circuit according to claim 6, wherein
the differential operational amplifier is a telescopic operational amplifier.

9. A sensor unit comprising the signal processing circuit according to claim 1.

10. A sensor unit comprising the signal processing circuit according to claim 6.
